(19) United States
(12) Patent Application Publication
(10) Pub. No.: US 2001/0017791 A1
(43) Pub. Date: Aug. 30, 2001

(54) Dynamic random access memory (DRAM) having ATD circuit

(75) Inventors: Akihiro Funyu, Kawasaki (JP); Shinya Fujioka, Kawasaki (JP)

Correspondence Address: ARENT FOX KINTNER PLOTKIN & KAHN, PLLC, 1050 Connecticut Avenue, N.W., Suite 600, Washington, DC, 20036-5339, US

(73) Assignee: FUJITSU LIMITED

(21) Appl. No.: 09/772,079

(22) Filed: Jan. 30, 2001

(30) Foreign Application Priority Data
Feb. 29, 2000 (JP) 2000-054147

(51) Int. Cl. G11C 5/00

(52) U.S. Cl. 365/189.07

(57) ABSTRACT

A high-speed DRAM, which comprises a plurality of separated operation circuits that perform accessing the memory cell array according to the detection of the transition of input signals and prevents a fatal malfunction even when glitches are generated in input signals, has been disclosed. The DRAM is designed so that erroneous data is not written to or read from by varying the possibility (sensitivity) with which a plurality of separated operation circuits initiate the operation according to the ATD signal.

### BACKGROUND OF THE INVENTION

The present invention relates to a dynamic random access memory (DRAM) or, more particularly, to a DRAM which has an ATD (Address Transition Detection) circuit that detects changes in address signals and control signals input from the outside and in which an internal circuit operates according to a detected signal in the ATD circuit.

In the case of a conventional general purpose DRAM, /RAS and /CAS are input as control signals and an address signal is accepted by the DRAM according to the state of or the change in /RAS and /CAS, and at the same time a data signal is input/output. More concretely, a pulse is generated at the fall of /RAS and from this pulse the rasz signal, which operates the RAS system peripheral circuits that relate to the access to the part specified by a row address latch signal and a row address, is generated. Moreover from this rasz signal, a control signal of the core of a DRAM memory cell array, excluding the selection signal of a column line and a sense amplifier activation signal, is generated. When /CAS falls, the transition of the column address signal is detected by the ATD circuits and the column address signal is latched by the ATD pulse generated accordingly. /CAS only specifies the duration of output enable.

It has been attempted to speed up the access cycle of a DRAM and a DRAM that operates the page mode by address multiplexing has been developed. The page mode can perform a high-speed read when column addresses are varied successively for a single row address. Recently, a synchronous DRAM (SDRAM) has been developed, which is based on the page mode and further speeds up the access cycle by employing a pipe line configuration in which a clock is supplied from the outside and the internal operation is synchronized with the clock (or internal clock generated from the clock). The SDRAM works speedily for the page mode operation but not for a random access in which row addresses are also varied.

The applicant has disclosed an SDRAM in International Publication WO98/No. 56004, which speeds up the random access in which row addresses are also varied by employing a pipeline configuration for the operation of the RAS system peripheral circuits that relate to the access to the part specified by row addresses. The SDRAM is referred to as FCDRAM here.

Though an SRAM can retain stored data without refresh, a problem in that the number of transistors constituting each memory cell is higher than that of a DRAM and it is difficult to enlarge the capacity occurs. Therefore the use of an FCDRAM, which is characterized in that it has a large capacity and is cheap, is now under investigation instead of the SDRAM. It is preferable that the interface of the FCDRAM is designed to operate with the same control signals as that of the SRAM to facilitate such a replacement.

The control signal of an SRAM, however, consists of /WE or /OE and is different from the control signal of an SDRAM or FCDRAM. For example, an external clock is supplied to the FCDRAM and the internal circuit of the FCDRAM operates in synchronization with the clock or the internal clock, but no external clock is provided to the SRAM and a problem in that it is impossible for the internal circuit to operate in synchronization with the clock or internal clock occurs.

Either way, it is necessary to activate plural circuits, without delay, that relate to the internal access operations of the DRAM according to access, in order to speed up the internal operations of the DRAM. As mentioned above, a general purpose DRAM uses an ATD circuit to detect the transition of column address signals, but it is possible to use the ATD circuit as a circuit that detects the transition of not only the column address signal but also the control signal, and also to start the operations of the plural circuits relating to the access operations by the ATD signal, which is the output of the ATD circuit.

In some cases, noise enters the address or control signals and an erroneous pulse with a very narrow width may be generated. This erroneous pulse is called a glitch, so the word is used here. It may be possible that an ATD signal is generated or the width of a pulse is reduced due to glitches when an ATD circuit is used in the configuration so that the operations of plural circuits are initiated, and all or a part of the plural circuits may start operations accordingly.

As mentioned above, in a general purpose DRAM, the latch of a row address signal and the operations of the RAS system peripheral circuits are initiated by the pulse generated at the fall of /RAS, and the column address signal is latched when the transition of the column address signal is detected by the ADT circuit. The cycle of the access operation is specified for the path between the latch of the column address signal and the output.

Also in the general purpose DRAM, if glitches occur in /RAS, /CAS, row address signals and column address signals, malfunctions become problematic. If a glitch occurs in /RAS, the latch of a row address signal and the operations of the RAS system peripheral circuits are initiated erroneously, or a problem that a part of circuits is not be initiated occurs, therefore, a circuit that detects the fall of /RAS is designed to detect only the fall of the correct /RAS by removing the glitch. To remove the glitch, only a signal stable for more than a predetermined time is detected, but it is necessary to delay the signal by the time according to the width of the glitch to be removed. The access cycle of the general purpose DRAM is slower than that of the FCRAM and there exists a sufficient time between the fall of /RAS and the transition of the column address signal, therefore the influence of the glitch on /RAS can be almost entirely removed, resulting in no problem. If a glitch occurs when a row address signal or a column address signal is latched, a problem in that an erroneous address is accessed occurs, but address signals are latched only when /RAS, from which the glitch is removed sufficiently, changes normally and that is not a problem.

If a configuration is made, in order to enable replacement of SRAM with FCDRAM, so that the ATD circuit is used to detect the transition of input signals of not only address signals but also control signals and the operations of plural circuits are initiated, an ATD signal is generated according to a glitch in an input signal and there is a possibility that all or a part of the plural circuits may malfunction accordingly. Therefore, it is necessary to remove the influence of a glitch, but there occurs a problem in that a sufficient time is not provided to remove the glitch for a high speed FCDRAM.

This problem occurs not only when the FCDRAM is used but also when the transition of input signals is detected to initiate the operations of the plural circuits in order to speed up the operation.

### SUMMARY OF THE INVENTION

The purpose of the present invention is to realize a DRAM in which these problems are solved and a fatal malfunction can be avoided even when a glitch occurs in an input signal in a high speed DRAM equipped with plural operation circuits that access the memory array according to the detection of the transition of input signals.

To realize the above-mentioned purpose, the dynamic random access memory (DRAM) of the present invention is characterized in that the possibilities (sensitivity) that the plural operation circuits initiate operation according to the ATD signal are varied so that erroneous data is not written to or read from the dynamic random access memory.

The circuits that access the memory cell array according to the detected signal (ATD signal) generated by the ATD circuit include such as the address latch circuit, the RAS system peripheral circuits relating to the access to the part pointed by the row address of the memory cell array, and the data input/output system circuit relating to the operations of writing or reading data. When the signal from the outside transits, the ADT circuit generates a pulse signal according to the change. The address latch circuit, the RAS system peripheral circuits and the data input/output system circuit initiate operations by the pulse signal as a trigger. The pulse signal is an ATD signal and all operations are initiated based on this signal. From this signal, the external address latch signal that activates the address latch circuit, the RAS system peripheral circuits, and the data input/output system circuit, the RAS system peripheral circuit activation signal, and the read/write operation command signal are generated.

The case in which a glitch occurs in an input signal and the pulse width of an ATD signal accordingly becomes narrower than that of a normal signal will be considered. In this case, if all the signals, which are supposed to be generated for the internal normal ADT signals, are generated and each circuit initiates operation normally, there occurs no problem, but if the width of an ATD signal becomes further narrower, some signals are not generated. This applies when an incorrect ATD signal of a narrow width is generated because of a glitch. The degree of the influence of malfunction differs depending upon which signal is generated or not. For example, if the RAS system peripheral circuit activation signal is not generated when an address is latched, the DRAM only reads the address and will not perform any other operations, therefore there occurs no problem. If, however, the RAS system peripheral circuit activation signal is generated when the address signal is not latched, an unintended address is accessed and this may lead to destruction of memory data. Even if the RAS system peripheral circuit activation signal is generated when the read signal or write signal is not generated, data is not damaged because the sense buffer or the write amplifier does not work though decoding is performed. However if the read signal or the write signal is generated when the RAS system peripheral circuit activation signal is not generated, undefined data is output or written. In the late write system, the written data may be replaced with undefined data.

In the DRAM of the present invention, therefore, the possibility (sensitivity) of initiating an operation is varied so that the possibility is the smallest for the data input/output system circuit that operates according to the read signal or write signal, and the possibility is higher for the RAS system peripheral circuit, and further higher for the address latch circuit. Thereby, a fatal malfunction, which may damage data, can be avoided even if a glitch occurs in an external input signal.

### BRIEF DESCRIPTION OF THE DRAWINGS

The features and advantages of the invention will be more clearly understood from the following description taken in conjunction with the accompanying drawings, in which:

FIG. 1 illustrates the total configuration of the DRAM in the embodiment of the present invention;

FIG. 2 illustrates the configuration of the ATD circuit in the embodiment;

FIG. 3 illustrates the configuration of the address latch signal generation (EALGEN) circuit in the embodiment;

FIG. 4 illustrates the configuration of the RAS system peripheral circuit activation signal generation (RASGEN) circuit and the data input/output system activation signal generation (CMDSEL) circuit in the embodiment;

FIG. 5 illustrates the configuration of the filter circuit in the embodiment;

FIG. 6 illustrates the time chart of the operation of the filter circuit in the embodiment;

FIG. 7 illustrates the time chart of the total operation of the DRAM in the embodiment; and FIG. 8 illustrates the sensitivity setting in the embodiment.

### DESCRIPTION OF THE PREFERRED EMBODIMENTS

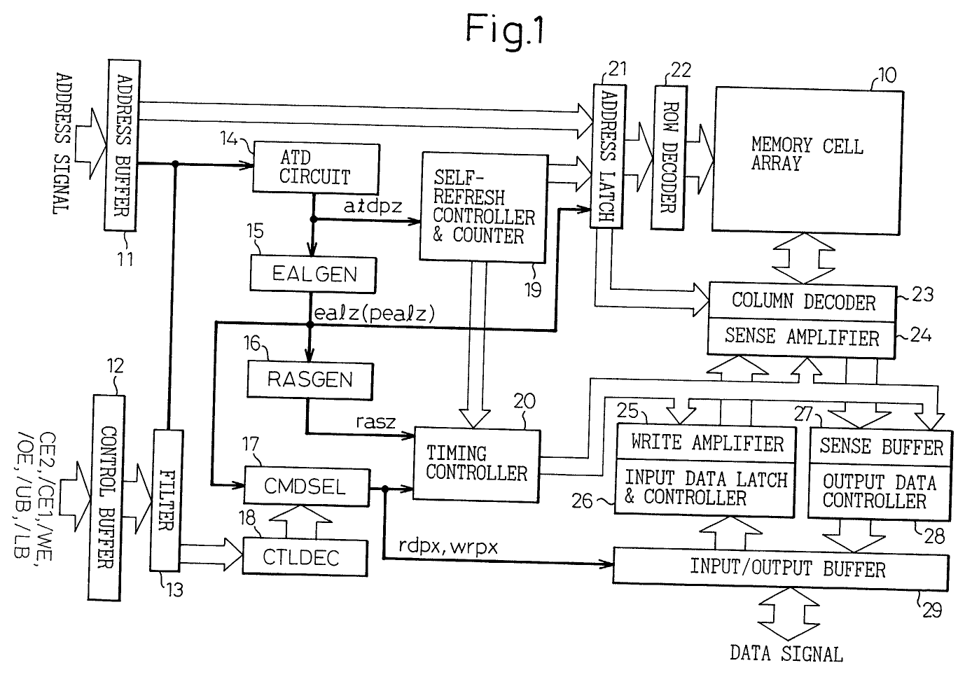

FIG. 1 illustrates the total configuration of the DRAM in the embodiment of the present invention. The DRAM, in which the operations of both the RAS system peripheral circuit and the data input/output system circuit are based on a pipe line configuration, is the FCDRAM, which provides a high-speed performance for random accesses as shown in International Publication WO 98/No.56004, but differs in that the transition of the control signals /CE, /WE, and /OE, and the address signal are detected to generate the ATD signal in the ATD circuit, and the operation of each internal circuit is performed according to the ATD signal, in order to enable the operation with the same control signals as that of the SRAM.

As shown in FIG. 1, the DRAM in the embodiment comprises a memory array 10, an address buffer 11 which accepts an address signal, a control buffer 12 which accepts control signals CE2, /CE, /WE, /OE, /UB, and /LB, a filter 13, an ATD circuit 14, an EALGEN circuit 15, an RASGEN circuit 16, a CMDSEL circuit 17, a CTLDEC circuit 18, a self refresh controller & counter 19, a timing controller 20, an address latch 21, a row decoder 22, a column decoder 23, a sense amplifier 24, a write amplifier 25, an input data latch & controller 26, a sense buffer 27, an output data controller 28, and an input/output buffer 29 to which or from which a data signal moves. As mentioned above, the DRAM in the embodiment has a configuration similar to that of the FCDRAM disclosed in International Publication WO 98/No.56004, therefore only the filter 13, the ATD circuit 14, the EALGEN circuit 15, the RASGEN circuit 16, and the CMDSET circuit 17, relating to the present invention are described here and a detailed explanation of other parts is omitted.

As shown in FIG. 1, after input to the control buffer 12 and glitches are decreased in the filter 13, the control signals CE2, /CE, /WE, /OE, /UB, and /LB are supplied to the ATD circuit 14 and the CTLDEC 18. These control signals are the control signals of the SRAM, and CE/2 and /CE are the chip selection signals, /WE is a write command signal, and /OE is a read command signal. The data width of this DRAM is 16-bit and the upper 8 bits, the lower 8 bits, or all 16 bits can be selected as a target of a certain operation, and /UB and /LB are the control signals that instruct the selection. The address signal is a 20-bit signal input to the address buffer 11, and supplied to the ATD circuit 14 and the address latch 21. In this DRAM, the ATD circuit 14 detects the address signal and the control signals that have passed through the filter 13 and outputs the ATD signal atdpz, and the internal circuits are activated by the ATD signal atdpz.

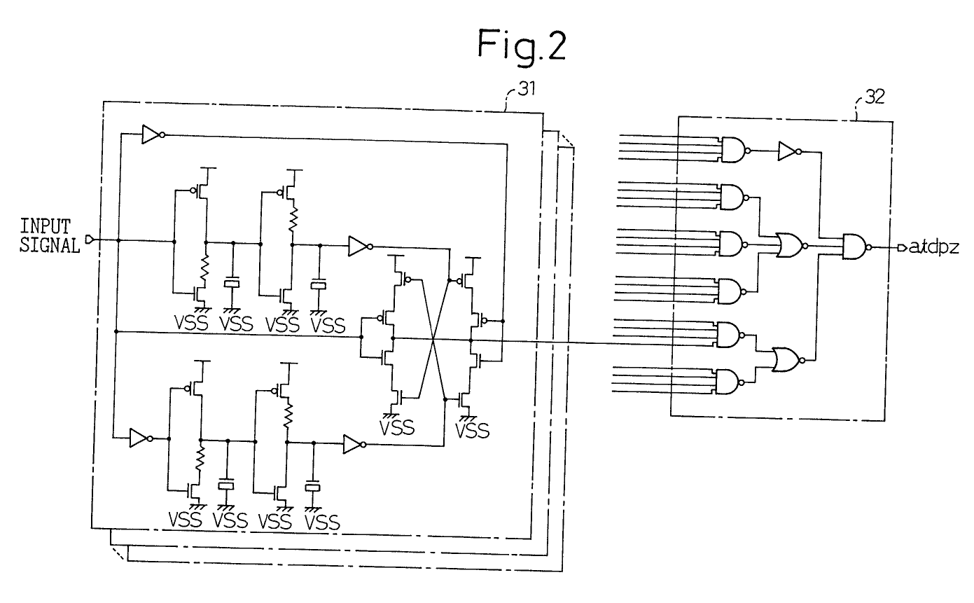

FIG. 2 illustrates the configuration of the ATD circuit 14. In the ATD circuit, which is widely known and a detailed description of which is omitted here, a signal change detection circuit (atdb) 31, which detects the change in each bit of the address signal and that in the control signals (excluding /UB /LB) that have passed through the filter 13, is provided for each signal. Therefore, 24 signal change detection circuits 31 are provided here. An ATD generation circuit (ATDGEN) 32 generates the ATD signal atdpz when one of the 24 signal change detection circuits 31 outputs the detection signal. The ATD signal atdpz is supplied to both the self refresh controller & counter 19 and the address latch signal generation circuit (EALGEN) 15. The DRAM has removed the refresh control of the DRAM by the controller of another device in order to be able to operate with the same signal as that of the SRAM, and employs the system in which a signal that arrives earlier between atdpz and a refresh request signal has priority to perform first in the DRAM, and the internal address or the external address is selected according to the operation to be performed and the signal is latched according to the address latch signal ealz, which is described later.

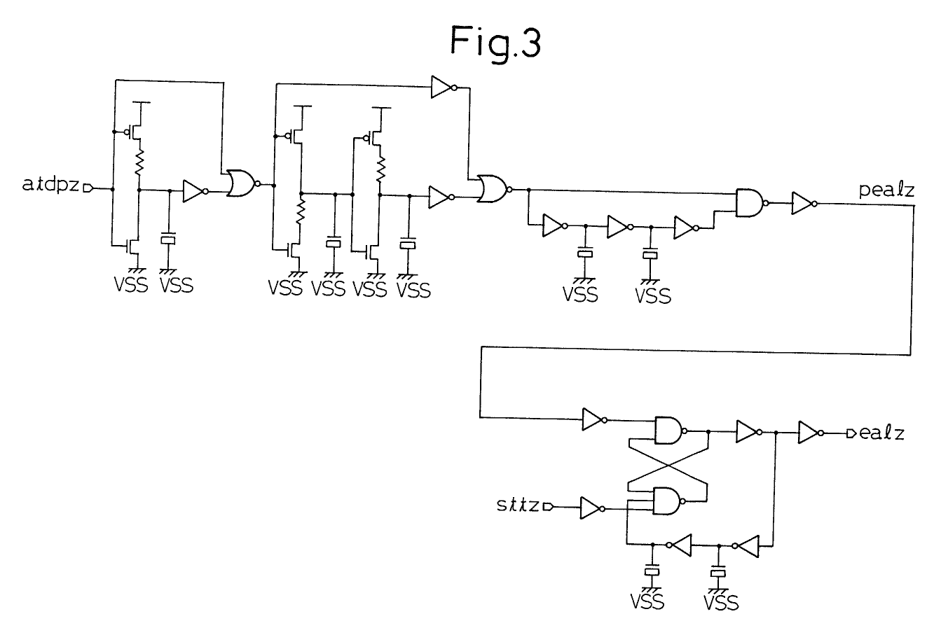

FIG. 3 illustrates the configuration of the EALGEN circuit 15. This circuit generates the address latch signal ealz from the ATD signal atdpz, and the signal pealz from a halfway part of the circuit. Though a detailed description is omitted here, the address latch signal ealz (pealz) generated by the EALGEN circuit 21 is applied to the address latch 21, and at the same time, to the RASGEN circuit 16 and the CMDSET circuit 17.

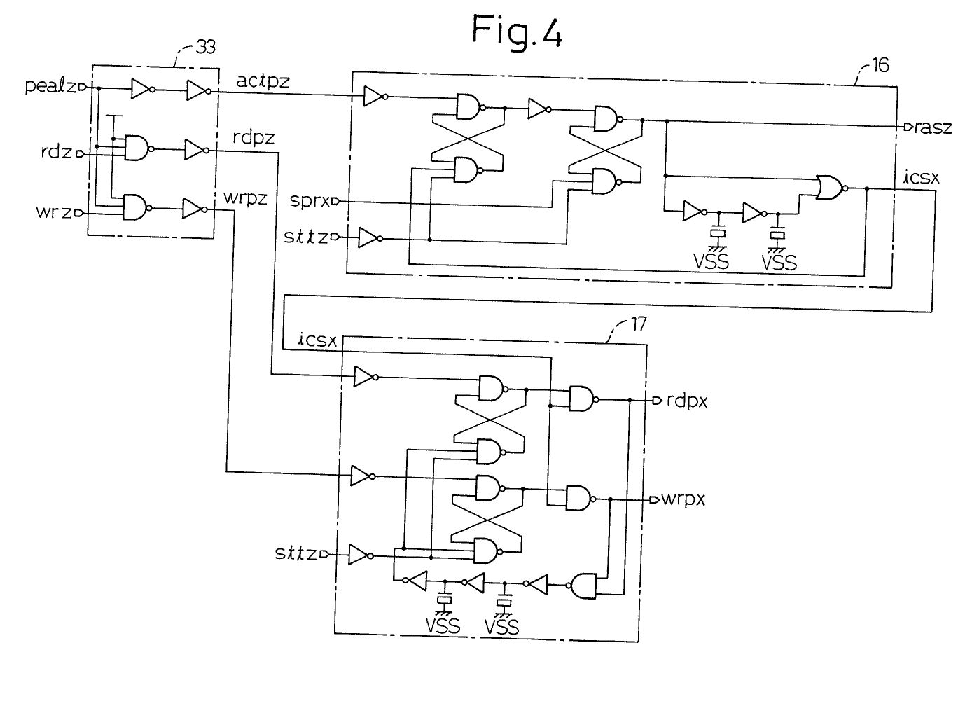

FIG. 4 illustrates the configuration of the RASGEN circuit 16 and the CMDSET circuit 17. As shown schematically, an actpgen circuit 33 is provided, which composes the signal pealz output from a halfway part of the above-mentioned EALGEN circuit 15, the read signal rdz (or write signal wrz) output from the CTLDEC 18, and the signal pealz. The RASGEN circuit 16 generates the RAS system peripheral circuit activation signal (rasz) that activates the RAS system peripheral circuits relating to the row address system from the signal actpz, which is a delayed and putout pealz signal from the actpgen circuit 33. The rasz signal is supplied to the timing controller 20.

The CMDSEL circuit 17 generates the read operation signal rdpx (or write operation signal wrpx) from the rdpz and wrpz signals output from the actpgen circuit 33 and the signal icsx output from the RASGEN circuit 16. The read operation signal rdpx (or write operation signal wrpx) is supplied to the timing controller 20 and the input/output buffer 29.

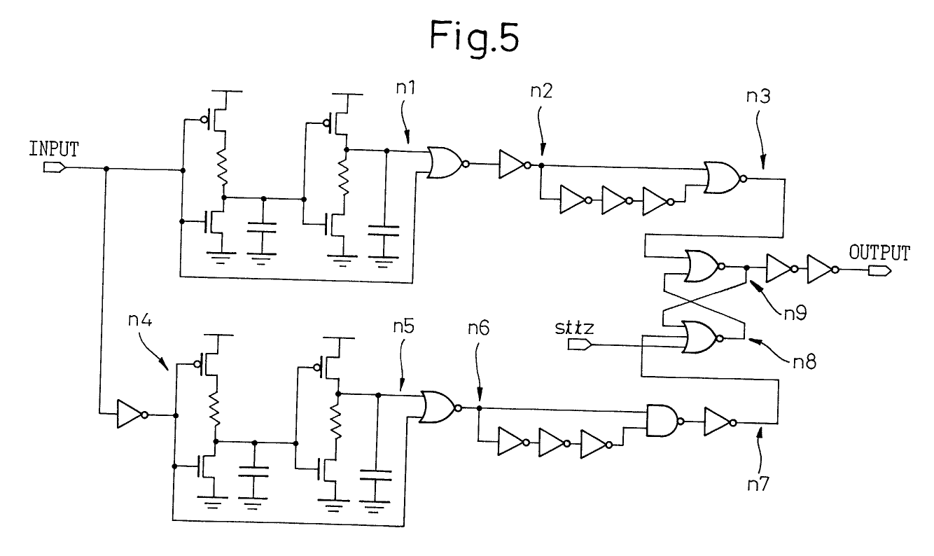

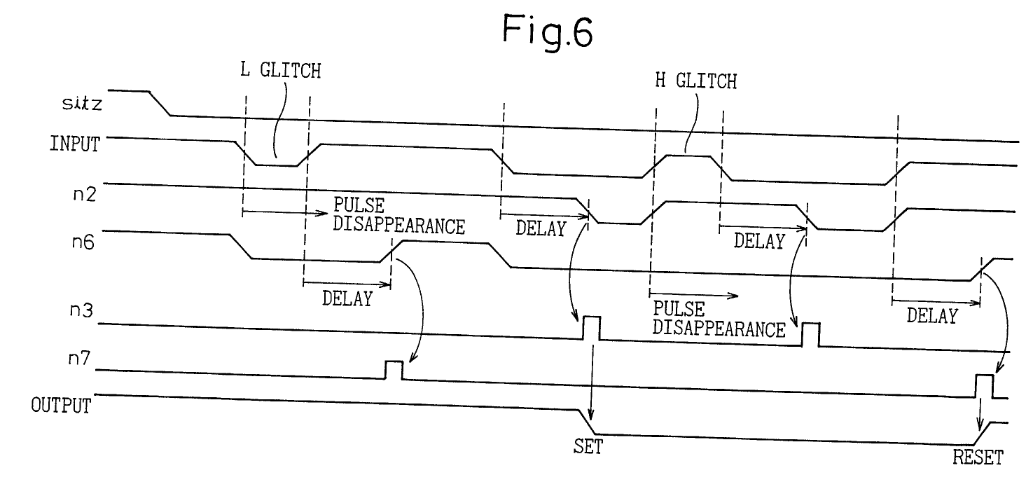

FIG. 5 illustrates the configuration of the filter circuit 13 and FIG. 6 illustrates the time chart that indicates the operation of the filter circuit 13. As mentioned above, it is preferable to remove glitches in input signals because they cause malfunctions. Though in the DRAM in this embodiment, the sensitivity to glitches is varied for each internal circuit to suppress the influence of glitches, the filter 13 is also designed to cut off glitches (noises) to remove the influence of glitches more surely. The filter circuit shown in FIG. 5 is provided for each control signal.

As shown in FIG. 5 and FIG. 6, the input control signal is shunted to opposite phase signal n4 generated through an inverter, and each signal is input to each one-side-effective delay device (a device that delays an L input). The output of an L input is delayed and, therefore, if a short L pulse is input, the pulse is removed from the output. As a result, each output n2 and n6 of the delay device is as shown in FIG. 6. That is, n2 and n6 are signals generated by removing L pulse noises and H pulse noises from external outputs, respectively. This means that n2 has a correct L transition information and n6 has a correct H transition information. Then, the H pulses n3 and n7 are made from the fall of n2 and the rise of n6, respectively, and each correct transition information is retrieved as a pulse from n2 and n6, respectively. Because, among the thus generated pulses, pulses having correct transition information are output alternately without fail from the n2 and n6 sides, a correct output can be generated through an NOR type flip-flop (FF) in the next stage. The output signal is output with a delay from the input that does not contain glitches (noises), and the amount of the delay is the pulse width of glitches (noises) that can be removed.

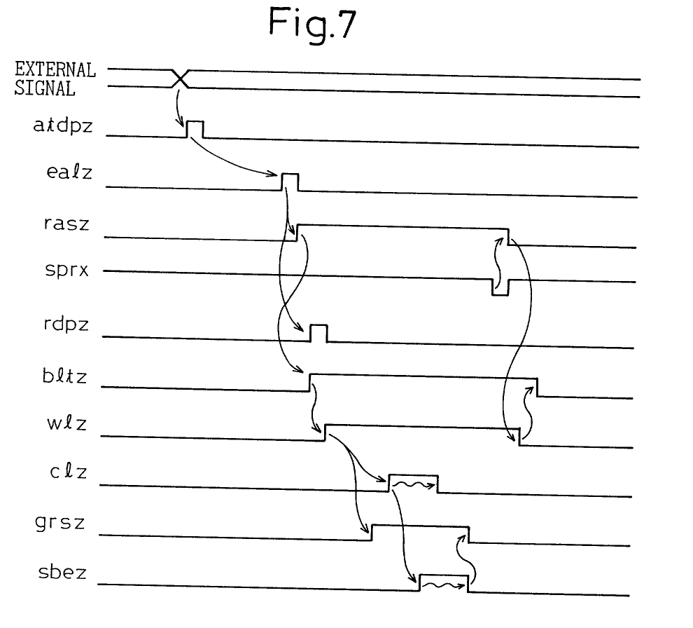

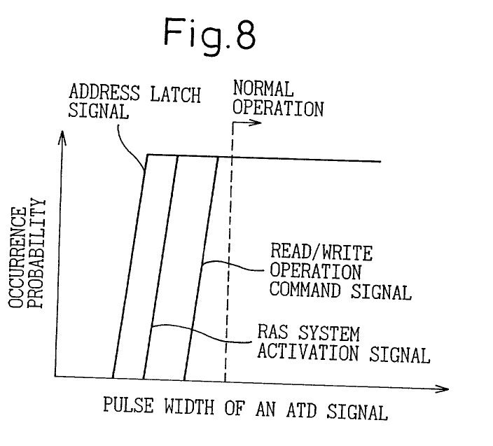

FIG. 7 is the time chart that shows the initiation signal at each part of the DRAM in the embodiment. With reference to FIG. 7, the operation timing of each above-mentioned part and the sensitivity to glitches are described below.

When each external signal exe.signal changes, the change is informed as an L pulse to the inside of the device through the signal change detection circuit (atdb) 31 in the ATD circuit 14. These L pulses are composed in the ATD generation circuit (ATDGEN) 32 and a pulse-shaped ATD signal atdpz is generated. The EALGEN circuit 15 extends the ATD signal atdpz and generates a pulse-shaped signal pealz from the end of the extended pulse in the edge trigger circuit. If the pulse width of atdpz changes and becomes narrower, the pulse is destroyed by the extension device and pearlz is not generated any more. That is, the possibility that the EALGEN circuit 15 generates pealz in response to the change of the external signal is lower than that of generation of the ATD signal atdpz. As a matter of course, the possibility of generation of the address latch signal ealz from pealz is lower than that of generation of atdpz, and the possibility of a latch in the address latch 21 is lower than that of generation of atdpz in the ATD circuit. The possibility is referred to as sensitivity here. Namely, the sensitivity of the address latch 21 is lower than that of the ATD circuit 14. However, the pulse width of pealz is determined by the amount of delay of the delay device, therefore the sensitivity is not determined by the size of pulse widths of atdpz and pealz. This will be described later.

The pealz signal generates actpz and rdpz (or wrpz) in the actgen circuit 33. In this circuit the sensitivity of actpz is increased than that of rdpz (or wrpz), and the response sensitivity is reduced by the use of the multi-input gate in the first input stage where rdpz (or wrpz) is generated. The sensitivity can be set by adjusting the response ability of each circuit, but it can also be adjusted, for example, by lengthening the gate. Because rdpz and wrpz are not output simultaneously, the same sensitivity is set.

The actpz and rdpz (or wrpz) signals generate rasz and rdpx (wrpx) respectively in the RASGEN circuit 16 and the CMDSEL circuit 17. If actpz and rdpz (or wrpz) have pulse widths more than a certain value, it is possible to change the FF of the input destination and generate rasz and rdpx (or wrpx). Once generated, the pulse widths of these signals are determined by the delay, therefore the pulse widths do not directly influence the sensitivity. The rdpx signal is used to switch the timing to output the core control signal between read and write or to activate the sense buffer 27.

When the rasz signal is generated (becomes H), the signal bltz becomes H with rasz as a trigger, and wlz also becomes H. The control signals of the core are thus generated (activated) starting from rasz successively.

The signal sprx is included in these signals and turns rasz to L and when rasz turns to L, wlz turns to L. The control signals of the core are thus deactivated starting from rasz successively and pre-charged.

As described above, plural control signals are generated starting from rasz, and the pulse width of the signals is influenced by the starting edge of the originating signal and made through the delay device to match the timing. On the other hand, the end of the pulse is influenced by the ending edge of the originating signal and made through the delay device to match the timing or the timing of the fall is determined by the delay from the rise of the pulse such as sbez. Therefore, the pulse width of the pulse signals generated after rasz is constant as long as the originating signal, that is rasz, is output and there is no relation in sensitivity between signals.

As described above, the sensitivity is the possibility that each circuit operates in response to the input signal, and the sensitivity has no direct relation with the width of the control signal generated in each circuit.

The sensitivity relation of the DRAM in the embodiment is shown in FIG. 8. When glitches generated in the signal input from the outside are small, the pulse width of the ATD signal is also small. Therefore in FIG. 8, the occurrence probability of generation of each operation signal for the pulse width of the ATD signal is used as the sensitivity. As shown schematically, as the pulse width of the ATD signal increases, the occurrence probability of each signal increases, but the occurrence probability of the address latch signal is high for a small pulse width, the occurrence probability of the activation signal of the RAS system peripheral circuit is second highest, and the occurrence probability of the read/write operation command signal is small. For a pulse width of a certain value or more, all the signals have the same occurrence probability (about 100%) and the normal operation is performed.

As mentioned above, according to the present invention, a fatal malfunction can be avoided even when glitches are generated in the input signal in the high-speed DRAM that has an ATD circuit activates plural separated operation circuit according to the detection of the transition of input signals. Therefore the high-speed DRAM that operates with the SRAM type I/O interface can be realized.

What is claimed is:

1. A dynamic random access memory comprising a memory cell array, a detection circuit that detects the transition of input signals, and a plurality of operation circuits that access said memory cell array according to the detection signal, wherein said plurality of operation circuits have different sensitivity, for initiation of their operation, to said detection signal.

2. A dynamic random access memory as set forth in claim 1, wherein said plurality of separated operation circuits include the RAS system peripheral circuit relating to the access to the part specified by the row address of said memory cell array and the data input/output system circuit relating to the read or write operation of data.

3. A dynamic random access memory as set forth in claim 2, wherein the sensitivity, with which the operation is initiated according to said detection signal in said data input/output system circuit, is lower than that of said RAS system peripheral circuit.

4. A dynamic random access memory as set forth in claim 2, wherein said plurality of separated operation circuits also include an address signal latch circuit.

5. A dynamic random access memory as set forth in claim 4, wherein the sensitivity with which the operation is initiated, according to said detection signal in said RAS system peripheral circuit, is lower than that of said address signal latch circuit.
